(19) United States
(12) Patent Application Publication
(10) Pub. No.: US 2014/0264652 A1
(43) Pub. Date: Sep. 18, 2014

(54) ACOUSTIC SENSOR WITH INTEGRATED PROGRAMMABLE ELECTRONIC INTERFACE

(71) Applicant: Invensense, Inc., Sunnyvale, CA (US)

(72) Inventors: Baris Cagdaser, Sunnyvale, CA (US); Martin Lim, San Mateo, CA (US); Fariborz Assaderaghi, Emerald Hills, CA (US)

(73) Assignee: Invensense, Inc., Sunnyvale, CA (US)

(21) Appl. No.: 13/950,240

(22) Filed: Jul. 24, 2013

Related U.S. Application Data
(60) Provisional application No. 61/786,334, filed on Mar. 15, 2013.

(51) Int. Cl. B81B 3/00

(52) U.S. Cl. CPC B81B 3/0027
USPC 257/416

(57) ABSTRACT

An integrated MEMS acoustic sensor has a MEMS transducer and a programmable electronic interface. The programmable electronic interface includes non-volatile memory and is coupled to the MEMS transducer. Using programmable electrical functions, the programmable electronic interface is operable to sense variations in the MEMS transducer caused by application of an acoustic pressure to the MEMS transducer.

### CROSS REFERENCE TO RELATED APPLICATIONS

This application claims priority to U.S. Provisional Application No. 61/786,334, filed on Mar. 15, 2013 and entitled “Acoustic Sensor With Integrated Programmable Electronic Interface”, by Cagdaser et al., the disclosure of which is incorporated herein by reference as though set forth in full.

### BACKGROUND

Microelectromechanical systems (MEMS) acoustic sensors (i.e. microphones) provide various advantages over the traditional electret condenser microphone (ECM) counterparts. For example, among many advantages, MEMS microphones are significantly smaller in volume, can tolerate higher temperatures during soldering (manufacturing), and provide a stable bias voltage over their lifetimes.

MEMS devices are subject to process variations caused by fabrication tolerances. Critical transducer parameters include, for example and without limitation, the diaphragm thickness of the MEMS microphone having to be tightly controlled in order to meet product specifications with high yield.

In capacitive MEMS acoustic sensors, mechanical variations include, without limitation, mechanical stiffness and stress-induced deflections compromising gap integrity between the acoustic sensing membrane and the sense electrode. Capacitor gap can further limit the performance of capacitive MEMS acoustic sensors by limiting the maximum bias voltage to avoid mechanical pull-in. The bias voltage has to be kept lower than the minimum pull-in voltage across the process. The bias voltage directly determines the amount of signal generated in response to the motion of the sensor. If a fixed bias voltage is used for different MEMS microphones irrespective of their processing/manufacturing condition, then it must be kept low to avoid pull-in for more compliant mechanical structures, which is a non-optimum value for sensors with stiffer mechanical structures, degrading their noise performance. Process variations and packaging stress variations require a significant margin of operating bias to prevent pull-in.

One common way of preventing yield loss due to large variations of the MEMS transducer is to achieve small manufacturing tolerances during the fabrication process. Such an approach, however, adversely impacts development time, cost, and vulnerability to process shift.

Accordingly, a MEMS device, used as a microphone, exhibiting high yield and reliability is needed.

### SUMMARY

Briefly, an embodiment of the invention includes an integrated MEMS acoustic sensor that has a MEMS transducer and a programmable electronic interface. The programmable electronic interface includes non-volatile memory and is coupled to the MEMS transducer. Using programmable electrical functions, the programmable electronic interface is operable to sense variations in the MEMS transducer caused by application of an acoustic pressure to the MEMS transducer.

A further understanding of the nature and the advantages of particular embodiments disclosed herein may be realized by reference of the remaining portions of the specification and the attached drawings.

### BRIEF DESCRIPTION OF THE DRAWINGS

FIG. 1 shows an integrated MEMS acoustic sensor 100 to include a mechanical element 102 and an electronic interface 104, in accordance with an embodiment of the invention.

FIG. 2 shows further details of the sensor 100, in accordance with an embodiment of the invention.

FIG. 3 shows relevant portions of an integrated MEMS acoustic sensor 300, in accordance with another embodiment of the invention.

FIG. 4 shows relevant portions of an integrated MEMS acoustic sensor 400, in accordance with yet another embodiment of the invention.

### DETAILED DESCRIPTION OF EMBODIMENTS

A MEMS acoustic sensor integrated with a programmable electronic interface and a non-volatile memory is disclosed. The programmable electronic interface includes the non-volatile memory and can be realized by CMOS circuitry in an embodiment of the invention. The non-volatile memory, which is used to store programming values of many types can be a one-time programmable memory (OTP), EEPROM, Flash, fuses, or any other suitable non-volatile type of memory. As will be evident, the programmable electronic interface provides superior product specification, testability, and process tolerance.

In an embodiment of the invention, a MEMS electronic interface, traditionally used for signal pick off, is enhanced by programmability to compensate for variations in the MEMS transducer (also referred to herein as a “MEMS device”). For example, in an embodiment of the invention, sensitivity variations, due to diaphragm thickness, can be compensated by adjusting the bias voltage or the pre-amplifier gain accordingly. In case of a MEMS acoustic sensor that is integrated with a non-volatile memory (NVM), factory programming of certain parameters of the electronic interface can further be stored on-chip—in the non-volatile memory—and automatically recalled during power-on. Besides compensating for process variations, a programmable interface with non-volatile memory can also provide die traceability, and observability of the electronic interface.

In accordance with various embodiments of the invention, MEMS devices (or “transducers”), are also subject to process variations caused by fabrication tolerances. Critical transducer parameters, for example but not limited to, the diaphragm thickness of the MEMS microphone has to be tightly controlled in order to meet product specifications with high yield. Another critical transducer parameter includes but not limited to, the gap between the diaphragm and the sense electrode has to be tightly controlled to meet product specifications.

Referring now to FIG. 1, an integrated MEMS acoustic sensor 100 is shown to include a mechanical element 102 and a programmable electronic interface 104, in accordance with an embodiment of the invention. The element 102 is a mechanical device whereas, the interface 104 is an electrical device. As is described in further detail below, the element 102 includes a MEMS transducer (or “MEMS device” as used herein). The electronic interface 104 uses certain programmable electrical functions to sense variations in the MEMS transducer caused by application of an acoustic pressure 106 to the MEMS transducer.

In an embodiment of the invention, the element 102 is a MEMS acoustic sensor that can be a microphone, as an example. As shown in FIGS. 3 and 4, the element 102 can be a suspended plate or a diaphragm, respectively. In the case of a diaphragm, increasing the acoustic pressure 106 causes the diaphragm to bend. In the case of the suspended plate, increasing the acoustic pressure 106 causes the suspended plate to experience a translational displacement.

As will be further evident below, the interface 104 is programmable and in this respect adjusts the resonance frequency and the phase of the element 102. The adjustment of phase and the resonance frequency is described in U.S. patent application Ser. No. 13/720,984 titled “Mode Tuning Sense Interface” which is hereby incorporated by reference in its entirety. In an exemplary embodiment, the element 102 and the interface 104 are integrated, formed on the same die (or “semiconductor”, integrated circuit, or “chip”). In other embodiments, the element 102 and the interface 104 are made on different die.

In operation, the acoustic pressure 106 is applied to the element 102 as an input. Changes in the acoustic pressure 106 lead to variation in the bending of the diaphragm, or variation in the translational displacement of the plate of 102, which in turn causes one or more electrical parameters of the element 102 to change. The interface 104 senses the change in electrical parameters of the acoustic pressure 106 and produces an electrical output signal that is a measure of the acoustic pressure. The electrical parameter sensed by the electronic interface 104 can be of many forms, for example but not limited to, the capacitance change between a suspended plate and a back-plate, as shown in FIG. 3, or the resistance change of piezoresistive elements embedded in diaphragm that bends when the acoustic pressure changes, as shown in FIG. 4.

The response of element 102 to the change in acoustic pressure 106 is a strong function of its mechanical parameters. For instance, in the example above where element 102 is a diaphragm, the mechanical displacement of the diaphragm in response to the acoustic pressure 106 is inversely proportional to the third power of the diaphragm thickness. Thus, a 10% increase in the diaphragm thickness can approximately result in 30% decrease in the diaphragm displacement, which is equivalent to over 2 dB reduction in mechanical sensitivity.

In the example above where the element 102 is a capacitive MEMS acoustic sensor, gap variations in the distance between the capacitor plate and the back-plate occur due to manufacturing variations. Furthermore, these gap variations additionally contribute to the sensitivity variation of the acoustic pressure sensor by affecting the rate of change of the MEMS capacitance with respect to displacement, as shown in FIG. 3.

As the response of the element 102 to the change in the acoustic pressure 106 varies, so does the electrical output 108 in a similar fashion. The interface 104 also has its own variations, which are typically substantially smaller than the mechanical ones. Having a largely varying input signal to the electronic interface 104, inevitably results in sub-optimal sensor performance. For example, in order to handle a high sensitivity transducer, the interface 104 needs to have lower gains, which results in insufficient amplification for low sensitivity cases and degrades the noise performance significantly.

The programmable electronic interface 104 causes substantial equalization of signal-to-noise (SNR) ratio, sensitivity, resonance frequency, phase delay, dynamic range, or gain among multiple acoustic sensors.

FIG. 2 shows further details of the sensor 100, in accordance with an embodiment of the invention. In FIG. 2, the element 102 is shown to include a MEMS transducer 202 and to receive the bias voltage, Vbias, 101 from the interface 104. As noted above, the bias voltage 101 is used to trim the MEMS transducer 202 allowing for a tighter sensitivity specification during production.

In FIG. 2, the interface 104 is shown to include a bias voltage source 209, an optional MEMS test block 204, a MEMS resonance frequency and phase adjustment block 206, a pre-amplifier 208, a phase adjust block 210, an electronic test block 212, also optional, a multiplexer (“mux”) 214, program registers 218, a non-volatile memory (“NVM”) 222, and a digital interface 220. The interface 104 is shown to receive the output of the MEMS transducer 202 and the trim input 224 as inputs and to generate the trim output 226, the electrical output 108, outputs of the blocks 204 and 206, and the bias voltage 101 provided to the MEMS transducer 202.

In another embodiment, trim values of the interface 104 are stored in the NVM 222. Thus, trim values determined at production can be permanently stored on-chip and recalled during power-on, which ensures that the part operates as trimmed outside the production environment. The NVM can be of many known types, examples of which are one-time programmable (OTP), EEPROM, Flash, or fuses.

Program registers 218 receive, as input, the output of the digital interface 220 and the output of the NVM 222. Program registers 218 output bias level 216a which are inputs for the bias voltage source 209, enable 216b which enables MEMS Test 204, adjust phase and resonance frequency 216c, generate gain 216d that is used by the pre-amplifier 208, and select 216e which is used to select phase adjustment or electrical test circuit in Mux 214. The output of the MEMS transducer 202 serves as input to the pre-amplifier 208. The output of the pre-amplifier 208 serves as input to the block 210. The blocks 210 and 212 provide inputs to the multiplexer 214, which selects to output either the output of the block 210 or the output of the block 212. More specifically, when the sensor 100 is in test mode, the multiplexer 214 via select 216e selects the output of the block 212 to couple onto the electrical output 108 and when the sensor 100 is not in test mode, the output of the block 210 is selected by the multiplexer 214 via select 216e and coupled onto the electrical output 108. The block 210 essentially adjusts the phase delay of the output of the pre-amplifier 208.

The electronic interface 104 can be programmed to perform functions activated by the end-user. Such functions can be, for example but not limited to, electrical testing of mechanical functionality, automatic correction of assembly shift, and dynamic adjustment for low level (whisper) or high level (concert) sound pressure modes. Any shift of sensor performance can be observed and appropriate parameters can be re-trimmed to achieve the intended performance. Adjustments available to the end-user can be in the form of, without limitation, gain, phase delay, or the resonance frequency of the mechanical element, which are all examples of programmable electrical functions. In the case where the sensor 100 is a microphone, such adjustments provide superior matching of multiple microphones in acoustic applications such as, but not limited to, beam forming and microphone directionality. In the case of sound level mode adjustment, the gain and bias can be adjusted to optimize performance with respect to transducer gain and electronic gain.

The NVM 222 is used to store certain parameters either during manufacturing or otherwise. In accordance with some embodiments of the invention, factory programming of certain parameters of the interface 104 are stored on-chip, in the NVM 222, and automatically recalled during power-on of the sensor 100. Besides compensating for process variations, the combination of the interface 104 with the NVM 222 provides die traceability and observability of the electronic system through the interface 104.

In operation, the acoustic pressure 106 is applied to the MEMS device 202 and in response thereto, the MEMS device 202 generates an output to the pre-amplifier 208. The pre-amplifier 208 amplifies the output of the MEMS device 202 by use of the gain 216d and outputs an amplified signal to the block 210. The block 210 adjusts the phase of the output of the pre-amplifier 208 after which the electrical output 108 becomes the output of the block 210, through the multiplexer 214.

Gain 216d is generated by the program registers 218, the latter using values stored in the NVM 222 to generate the gain 216d. The program registers also provide an input 216c for phase and resonance frequency adjustment in block 206 which trims the resonance frequency of the MEMS device 202 and adjusts the phase response of the MEMS device 202. Another program register output 216a is further determinative of the bias voltage source 209 which generates the bias voltage 101. The foregoing being examples of the programmable electronic functions of the interface 104.

The digital interface 220 is shown coupled to the programmable registers 218 and is used to interface with the trim input 224 and trim output 226. Advantageously, a user may trim the signal path through trim input 224. The trim input 224 and the trim output 226 are used to identify characteristic patterns of acoustic sensor performance during calibration or testing of the sensor 100. The trim output 226 is indicative of the trim of the signal path and generated by the programmable registers 218, which provides the same to the digital interface 220. In the case where the sensor is a part of or interacts with a microphone, the digital interface 220 is used to communicate with a microphone.

The signal path gain from acoustic input 106 to the electrical output 108 can be trimmed, for example and without limitation, by adjusting the bias voltage 101 in the case where the sensor 100 is a capacitive MEMS microphone. Such an adjustment provides substantially constant transducer sensitivity and results in substantially constant signal-to noise-ratio (SNR) performance across the devices built on the same production process. A further advantage of trimming the bias voltage 101 is the ability to use the most optimal bias voltage level that is still below the pull-in point for each capacitive MEMS microphone device, or sensor 100. Thus, building redundant performance and performance margin into the interface 104 is avoided. Parametric optimization may include but is not limited to SNR, sensitivity control, or high dynamic range.

In the embodiment of FIG. 2 and as previously noted, the interface 104 is made programmable. In such a case, as an example, transducer variation due to mechanical sensitivity can be advantageously compensated by adjusting the signal gain, i.e. gain 216d. Programmability can also be used to enhance testability and observability of the sensor 100, which can further improve the test accuracy and reduce the test cost. Some of the many advantages of using the programmable electronic interface 104 in the MEMS acoustic sensor are additionally explained below.

Providing a tighter sensitivity variation specification is one of the numerous benefits of the interface 104. State-of-the-art MEMS microphones have as high as ±3 dB (40%) sensitivity variation, which becomes a limiting factor in acoustic applications such as implementing microphone directionality or noise cancellation. A much tighter sensitivity specification is achieved by the embodiments of FIGS. 1 and 2, during production, by trimming bias voltage source 209, MEMS test blocks 204, MEMS resonance frequency and phase adjustment 206 and Pre-amp, 208.

During testing of the sensor 100, the MEMS test block 204 stimulates the MEMS device resulting in an electrical output 108 that should be a predetermined output when the sensor 100 is operating properly. The same stimuli also reveal resonance frequency and phase of the MEMS device, which is adjusted by 206. The adjustment of phase and resonance frequency is described in U.S. patent application Ser. No. 13/720,984, titled “Mode Tuning Sense Interface” which is hereby incorporated by reference in its entirety. To this end, testing is performed without the application of the acoustic pressure 106 and rather uses controlled input through the MEMS test block 204.

Certain applications for acoustic sensor 100 such as noise cancellation require substantial matching or equalization of output among multiple sensors 100. Programmable electronic functions, generated by the interface 104, provide this matching during manufacturing. For example and without limitation parameters that have desirable matching values include sensitivity, signal to noise ratio (SNR), and dynamic range.

The electrical performance of device 100 is further improved by reducing process variations of the electrical parameters. For example and without limitation, current consumption of device 100 can be trimmed to achieve a substantially constant value by trimming it against variations of the bias circuit. Such bias variations can be caused by, without limitation, bandgap reference variations or process variations of on-chip resistors. Thus, sensor 100 can achieve tighter current consumption specifications. Programmability of the bias can further improve temperature stability of the interface electronics by trimming the on-chip bandgap reference to the most optimal value.

In another embodiment of the invention, full-scale (FS) range and the output offset of the sensor 100 can be adjusted to provide larger dynamic range in cases where higher supply voltage is available. Such functionality can be permanently stored in the NVM 222, or automatically detected by the interface 104 by monitoring the supply level.

The interface 104 also improves testability and observability of MEMS acoustic sensor electronics. For example, a limited number of interface pins can have multiple functionalities in addition to their main purpose, i.e. analog output pin can also be used to observe one, two, or many internal node voltages and currents. Such observability enables rapid circuit trim, characterization, and debug. The circuit, for example and without limitation, can be CMOS or BiCMOS.

FIG. 3 shows relevant portions of an integrated MEMS acoustic sensor 300, in accordance with another embodiment of the invention. In FIG. 3, the acoustic pressure 106 is shown being applied to the MEMS device 302. The MEMS device is shown coupled to a pre-amplifier 304, which is analogous to the pre-amplifier 208 of FIG. 2. The pre-amplifier 304 is shown to receive the input for gain 216d and an output from the MEMS device 302.

This configuration is for illustration purposes to describe a mass-spring characteristic of an acoustic pressure sensitive plate or membrane. The MEMS device 302 is shown to include a multitude of springs 314 and 316, each of which is shown coupled to capacitor plate 310 on one end and to mechanical ground at an opposite end. The mechanical ground is typically formed from a silicon substrate or wafer. The moveable structure capacitor plate 310 is displaced relative to the stationary structure back plate 318, to form a variable capacitor of MEMS device 302. The displacement of the capacitor plate 310 changes the capacitance of the MEMS device 302. This displacement is a function of the variation in the acoustic pressure 106. The capacitor plate 310 is further shown coupled to the bias voltage 308, which is analogous to the bias voltage 101 of FIG. 2. The varying capacitance is the input to the pre-amplifier, 304 through electrical connection to the back plate 318. Alternatively, not shown, the bias voltage 308 can be coupled to the stationary back plate 318 and the capacitor plate 310 is electrically connected to pre-amplifier 304. The pre-amplifier 304 ultimately generates the electrical output 108 much in the same manner as that shown in FIG. 2. Each of the springs 314 and 316 have associated therewith a spring constant kₓ, which influences the amount of displacement of movable capacitor plate 310 for a given acoustic pressure input 106. For those skilled in the art can recognize various plate spring configurations for an acoustic sensitive structure as well as the conventional membrane structure where its compliance is derived from its relative thinness.

In the embodiment of FIG. 3, as in FIG. 2, the programmability of the signal path gain allows the sensitivity of the element 302 to be compensated by adjusting the signal gain 216d after the bias voltage 308. This can be implemented by, for example, adjusting the feedback capacitor of a trans-capacitance amplifier (pre-amplifier 304), or adjusting the feedback resistance of a trans-resistance amplifier, or adjusting the gain of a capacitive or resistive gain stage. Such an adjustment alone, however, requires the bias voltage 308 to be set at a level that is at the lowest pull-in level expected across the production, and limits the sensor performance.

Programmable electronic interface can be further used to enhance test and production, as well as the end application. For example, trans-capacitance amplifier used as the pre-amplifier 304 of the capacitive MEMS acoustic sensor 300, can be electronically reconfigured to perform measurements of critical transducer parameters such as the gap between the suspended movable capacitor 310 and the back-plate 318, as this gap is one of the direct contributors to the acoustic sensitivity of the MEMS device 302.

An electrical test can also be activated by using the programmable interface to directly measure the mechanical resonance frequency of the acoustic sensor, or the MEMS device 302. The ability to directly measure the gap between the plates, and estimating the mechanical stiffness through the resonance frequency measurement enables accurate selection of the most optimal trim values such as the bias voltage of a capacitive MEMS acoustic sensor 300, among other benefits.

FIG. 4 shows relevant portions of an integrated MEMS acoustic sensor 400, in accordance with yet another embodiment of the invention. In FIG. 4, the MEMS device 402 is shown coupled to the pre-amplifier 408, which is analogous to the pre-amplifier 208 in FIG. 2 and the pre-amplifier 304 in FIG. 3. The pre-amplifier 408 is shown to receive input from the MEMS device 402 and the gain 216. The MEMS device 402 includes a diaphragm 414 on top and either side of which are formed piezoresistor elements 412. Acoustic pressure 106 is applied to the diaphragm 414 of the element 402 and in response thereto, the diaphragm 414 bends. The piezoresistor elements 412 are shown connected to mechanical ground on two ends that are opposite of that which receives the acoustic pressure 106. A bias voltage, Vbias, 404 is shown from the bias voltage source 410 to the MEMS device 402 and causes adjustments of the MEMS device 402, as discussed below. The higher the bias voltage 404, the greater the adjustments to the MEMS device 402.

The transducer sensitivity of the MEMS device 402, of FIG. 4, can also be compensated against process variations by adjusting the bias voltage 404 of the piezoresistor elements 412, which are typically arranged in a Wheatstone bridge configuration. In terms of the system performance, this approach is similar to adjusting the bias voltage of the capacitive MEMS acoustic sensor by delivering a substantially constant transducer sensitivity, thus, achieving a substantially constant SNR performance across the process.

In the embodiment of FIG. 4, the programmable interface, a part of which is shown to comprise the pre-amplifier 408, can compensate for additional mechanical variations, for example and without limitation, the resonance frequency of the MEMS device or the phase delay of the signal through the MEMS device. Resonance frequency of these mechanical elements can be adjusted by, for example and without limitation, by force-feedback applied to the mechanical element. Phase delay of the mechanical elements, can be compensated by phase adjustment in the form of delay/advance provided in the signal path.

Although the description has been provided with respect to particular embodiments thereof, these particular embodiments are merely illustrative, and not restrictive.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular embodiments have been described herein, latitudes of modification, various changes, and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit.

What we claim is:

1. An integrated MEMS acoustic sensor comprising,
a MEMS transducer; and
a programmable electronic interface including a non-volatile memory, the programmable electronic interface being coupled to the MEMS transducer and, using programmable electrical functions, operable to sense variations in the MEMS transducer caused by application of an acoustic pressure to the MEMS transducer.

2. The integrated MEMS acoustic sensor of claim 1, wherein the MEMS transducer comprises a movable structure and a non-movable structure, wherein the distance between the movable structure and the non-movable structure is influenced by acoustic pressure on the movable structure.

3. The integrated MEMS acoustic sensor of claim 2, wherein the programmable electronic interface is operable to influence a bias level on the movable structure.

4. The integrated MEMS acoustic sensor of claim 2, wherein the programmable electronic interface is operable to influence a bias level on the non-movable structure.

5. The integrated MEMS acoustic sensor of claim 1, wherein the programmable electronic interface is operable to influence an electronic gain of the sensor.

6. The integrated MEMS acoustic sensor of claim 1, wherein the MEMS transducer has associated therewith a phase delay and wherein the programmable electronic interface is operable to substantially compensate for the phase delay by adjusting a phase of the MEMS transducer.

7. The integrated MEMS acoustic sensor of claim 1, wherein the MEMS transducer has associated therewith a resonance frequency and wherein the programmable electronic interface is operable to substantially compensate for the resonance frequency by adjusting the resonance frequency of the MEMS transducer.

8. The integrated MEMS acoustic sensor of claim 1, further including more than one acoustic sensor and wherein the programmable electronic interface is operable to cause substantial equalization of signal-to-noise (SNR) ratio, sensitivity, resonance frequency, phase delay, dynamic range, or gain among the more than one acoustic sensor.

9. The integrated MEMS acoustic sensor of claim 1, wherein the non-volatile memory is operable to store programming values and further operable to use the programming values upon power-on of the integrated MEMS acoustic sensor.

10. The integrated MEMS acoustic sensor of claim 1, wherein the MEMS transducer has associated therewith acoustic properties and the programmable electronic interface is further operable to enable electrical stimuli of the MEMS transducer to simulate a response to an acoustic pressure input.

11. The integrated MEMS acoustic sensor of claim 2, wherein the MEMS transducer has associated therewith acoustic properties and the programmable electronic interface is further operable to enable electrical stimuli of the MEMS transducer to modify the distance between the movable structure and the non-movable structure.

12. The integrated MEMS acoustic sensor of claim 1, wherein the MEMS transducer includes a capacitor having a capacitance associated therewith and including a capacitor plate that is displaced upon application of the acoustic pressure onto the MEMS transducer, the MEMS transducer being operable to produce a change in the value of the capacitance in response to variations in the acoustic pressure.

13. The MEMS acoustic sensor of claim 12, further including a plurality of MEMS transducers and wherein the programmable electronic interface is operable to adjust a bias voltage across the capacitor to provide substantially constant transducer sensitivity, signal-to-noise ratio, and optimal bias point for each individual MEMS transducer, of the plurality of MEMS transducers.

14. The integrated MEMS acoustic sensor interface of claim 1, wherein the MEMS transducer includes one or more resistors each having a resistance associated therewith, the resistance of the one or more resistors changing upon the application of the acoustic pressure to the MEMS transducer, the MEMS transducer being operable to produce a change in the value of one or more resistors in response to variations in the acoustic pressure.

15. The MEMS acoustic sensor of claim 14, wherein the programmable electronic interface is operable to adjust a bias voltage across the one or more resistors to provide substantially constant transducer sensitivity and signal-to-noise ratio.

16. The MEMS acoustic sensor of claim 1, wherein the programmable electronic interface includes at least one pre-amplifier and is operable to adjust a total gain of a signal path in the at least one pre-amplifier, the at least one pre-amplifier providing signal gain.

17. The MEMS acoustic sensor of claim 1, wherein the programmable electronic interface includes at least one phase-adjustment block, the programmable electronic interface being operable to adjust a phase of a signal path in the at least one phase-adjustment block.

18. The MEMS acoustic sensor of claim 9, wherein the programmable electronic interface is operable to operate at different acoustic signal levels by changing an output offset level determined by the programming values or a supply voltage level.

19. The MEMS acoustic sensor of claim 1, wherein the MEMS transducer and the programmable electronic interface are formed on a same die.

20. The MEMS acoustic sensor of claim 1, wherein the MEMS transducer and the programmable electronic interface are formed on different dies.

21. The MEMS acoustic sensor of claim 1, wherein the MEMS acoustic sensor is a microphone.

22. The MEMS acoustic sensor of claim 2, wherein the movable structure has associated therewith a resonant frequency, the movable structure is displaced to adjust the resonant frequency.

23. The MEMS acoustic sensor of claim 1, wherein the non-volatile memory comprising one of a one-time programmable (OTP) memory, EEPROM, Flash, or fuses.

24. An acoustic sensing device comprising
a MEMS transducer;
a substrate; and
a structure attached to the substrate,
wherein the structure is displaced in the presence of an acoustic pressure, further wherein the substrate includes a programmable electronic interface including non-volatile memory, the programmable electronic interface being coupled to the MEMS transducer.

25. The acoustic sensing device of claim 24, wherein the substrate includes CMOS circuitry.

26. The acoustic sensing device of claim 24, wherein the structure is comprised of silicon.
